(19) United States
(12) Patent Application Publication
(10) Pub. No.: US 2026/0255481 A1
(43) Pub. Date: Aug. 27, 2026

(54) DEVICE INCLUDING BOARD MEMBER AND MANUFACTURING METHODS

(71) Applicant: Infineon Technologies AG, Neubiberg (DE)

(72) Inventors: Chee Yang Ng, Muar (MY); Nurfarena Othman, Melaka (MY)

(21) Appl. No.: 19/546,601

(22) Filed: Feb. 23, 2026

(30) Foreign Application Priority Data
Feb. 24, 2025 (DE) 102025106855.0

(51) Int. Cl. H05K 1/11; H05K 1/181; H05K 3/00

(52) U.S. Cl. CPC H05K 1/114; H05K 1/181; H05K 3/0047; H05K 3/0097; H05K 2201/09563; H05K 2201/10522

(57) ABSTRACT

A device includes a board member having a plurality of areas. Pads for chip bonding are provided in the areas which are coupled to conducting portions on an opposite side of the board member via electrically conducting paths through through holes provided on borders between areas.

### TECHNICAL FIELD

The present application relates to devices including board members for bonding to chips and associated manufacturing methods.

### BACKGROUND

In the manufacturing of electronic devices, chips including one or more semiconductor devices may be bonded to pads (also referred to as landing pads herein ) for electrical contacting of the chip. These pads and associated wiring may take up a comparatively large area. Together with conductive portions in the chip, parasitic capacitances are formed.

These parasitic capacitances may adversely affect the performance of the electronic device. Such adverse effects may be particularly pronounced in radio frequency (RF) applications like antenna tuning. For such applications, if the chip comprises one or more switches, the parasitic capacitances increase the off-capacitance of the switch, i.e. capacitance when the switch is switched off. For radio frequency applications, a low off-capacitance of the switch is desirable.

### SUMMARY

According to an embodiment, a device is provided, comprising: a board member comprising a first area and a second area on a first side of the board member, the first area including a first electrically conducting pad for bonding to a first chip, and the second area including a second electrically conducting pad for bonding to a second chip. The board member further comprises: a through hole between a first side and a second side opposite the first side and arranged at a border between the first area and a second area, a first electrically conducting path from the first electrically conducting pad through the through hole to a first conducting portion on the second side opposite the first area, and a second electrically conducting path from the first electrically conducting pad through the through hole to a second conducting portion on the second side opposite the second area.

According to another embodiment, a device is provided, comprising: a board member including an electrically conducting pad on a first side, an indentation on a side face of the board member, and an electrically conducting path from the electrically conducting pad through the indentation through an electrically conducting portion on the second side. Furthermore, the device comprises a chip bonded to the electrically conducting pad.

Such a device according to an embodiment may be manufactured by singulating the first mentioned device above with chips bonded to the first and second electrically conducting pads, respectively.

According to a further embodiment, board members as mentioned above may be manufactured by stacking a plurality of boards and drilling the respective through holes for the plurality of boards in one drilling operation through all the stacked boards.

The above embodiments give merely a brief overview over some embodiments and are not to be construed as limiting.

### BRIEF DESCRIPTION OF THE DRAWINGS

FIG. 1A is a top view of a device according to an embodiment.

FIG. 1B is a top view of a device according to a further embodiment, derived from the device of FIG. 1A.

FIG. 1C is a cross-sectional view for further illustrating the embodiments of FIGS. 1A and 1B.

FIG. 2 is a cross-sectional view for illustrating parasitic capacitances.

FIG. 3 is a top view of a device according to a further embodiment.

FIG. 4A is a top view of a device according to a further embodiment, and FIG. 4B is a corresponding bottom view.

FIG. 5 is a flowchart illustrating a method according to an embodiment.

FIG. 6 is a flowchart illustrating a method according to a further embodiment.

### DETAILED DESCRIPTION

In the following various embodiments will be discussed in detail. These embodiments are given as an example only and are not to be construed as limiting. For example, while embodiments may show certain dimensions and certain numbers of elements, like pads, through holes, and the like, and specific arrangements of the same, in other embodiments the numbers and arrangements may vary in other embodiments.

Features from different embodiments may be combined to form further embodiments. Variations or modifications described for one of the embodiments are also applicable to other embodiments unless noted otherwise.

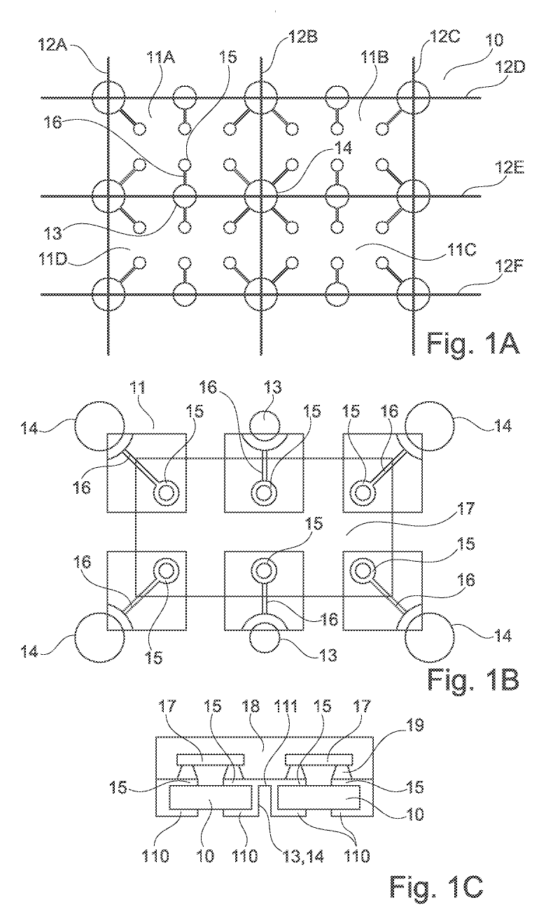

FIG. 1A is a top view of a device according to an embodiment, comprising a board 10. Board 10 may for example be made of resin. For instance, materials conventionally used for printed circuit boards (PCB) may be used as material for board 10. The terms ‘board’ and ‘board member’ are used herein interchangeably.

The board 10 has a plurality of areas 11A, 11B, 11C and 11D. The number of four areas is merely a simple example. The areas are separated by lines 12A-12F. In a manufacturing process, lines 12A-12F are saw lines along which a singulation is performed to manufacture single devices.

In each areas 11A-11D, pads 15 are arranged, in the example shown six pads per area, serve as landing pads for bonding chips thereto. Furthermore, through holes 13 and 14 are shown leading from the side of board 10 shown in FIG. 1A (first side) to a second side opposite the first side. Electrically conducting paths 16 lead from the pads 15 to respective through holes 13 or 14. Through holes 13 are arranged at the border between two of the areas 11A-11D, and through holes 14 are arranged at corners, such that they may be shared (unless the respective through hole is at the border of board 10) by four areas 11A-11D.

The electrically conducting paths 16 may have a low width, in particular smaller than a diameter of the respective pad 15. Generally, the diameter of the pads 15 may also be kept small, for example at a minimum size necessary for bonding the chip thereto, and a width of electrically conducting path 16 may be set to a minimum width which can be reliably manufactured and which provides the necessary current carrying capabilities to or from the chip bonded to the respective pad in terms of resistance and maximum current to be carried.

The number of six pads per area is not to be construed as limiting, and more or less pads may be provided.

FIG. 1B shows a single area in more detail, with a chip 17 bonded to pads 15. After singulation, indentations (essentially half-circular or quarter-circular) remain at the edge of the device, as can be seen in FIG. 1B.

FIG. 1C shows an example cross-sectional view for two adjacent areas and chips 17 each bonded to two respective pads 15 with bonding material 19. Furthermore, chips 17 are encased in a mold 18. From the pads 15, the electrically conductive path 16 runs through respective through holes 13 or 14 to conducting portions 110 at an opposite side of board 10. As can be seen in FIG. 1C for the shared through hole, in some embodiments separate paths may run through the through hole, but the paths may also commonly formed in the through hole. When then singulation along line 12A-12F of FIG. 1A is performed, these are separated into separate conducting paths through the through holes.

In FIG. 1C, as marked with reference numeral 111, furthermore adjacent pads are linked covering the through hole. This prevents mold material 18 from entering the through hole during the manufacturing process. When the singulation is performed, this bridge 111 is cut, thus separating the pads. In other embodiments, this bridge 111 may be omitted.

By providing such a structure as illustrated with respect to FIGS. 1A to 1C, small pads 15 may be used, the through holes are offset from the chip, and only small electrically conducting paths 16 may be used. This reduces

the overlap between metallic area formed by pads 15 and electrically conducting portion 16 with the chip. In conventional solutions, often larger pads are used, with through holes provided concentrically with the pads, which may lead to a higher overlap and therefore to larger parasitic capacitances.

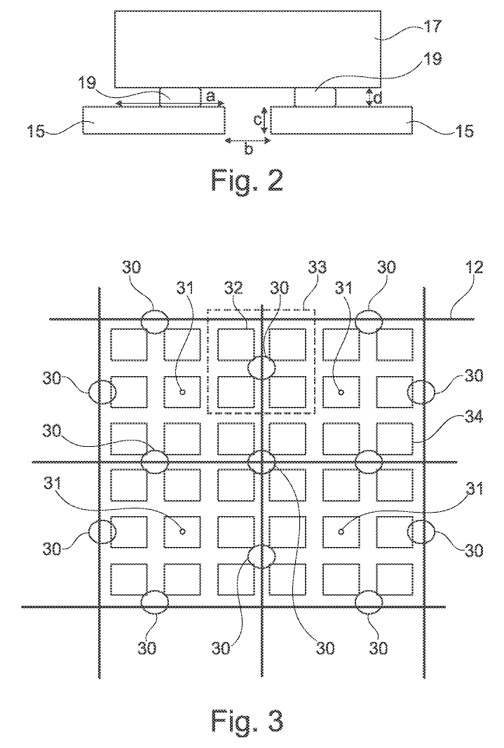

Parasitic capacitances will be further explained referring to FIG. 2. Here, a chip 17 is shown above and bonded thereto via bonding material 19. The parasitic capacitances depend on a pad size overlapping with chip 17, which may be reduced by the approach with the shared through holes at boundaries between areas discussed above. Furthermore, the capacitance depends on the distance d between the pads, a metal thickness c, and a distance b from chip 17 to pads 15. As the pads 15 may be made smaller than in conventional solutions, also parameter d, i.e. the distance between the pads, may be increased, which also decreases the parasitic capacitance in some embodiments. In case chip 17 for example includes switches, the off-capacitance of these switches is reduced. This is in particular advantageous for radio frequency applications like antenna tuning.

Furthermore, a reduction of the number of vias (through holes through the board) may be obtained as areas share through holes, which in some embodiments may reduce manufacturing costs.

FIG. 3 illustrates further examples with four areas separated by lines 12. In each area, nine pads with corresponding electrically conducting paths, shown as squares 34, are arranged in a 3 x 3 array.

Through holes 30 are placed at boundaries between areas, i.e. on lines 12. As can be seen, many through holes are arranged such that they can serve four pads (two pads in each of two adjacent areas), for example through hole 30 in a region marked by reference numeral 33.

It is noted that the middle pad in each area has its own through hole 31, as the middle pad is not adjacent to any border. Nevertheless, even if the middle pads have their own through holes 31, compared to an arrangement where each pad has its through hole the number of through holes can be reduced by more than 60% in this way, and many pad sizes may be reduced, and the through holes are more remote from the respective pad compared to through hole 31. As explained above, this may contribute to reducing parasitic capacitances.

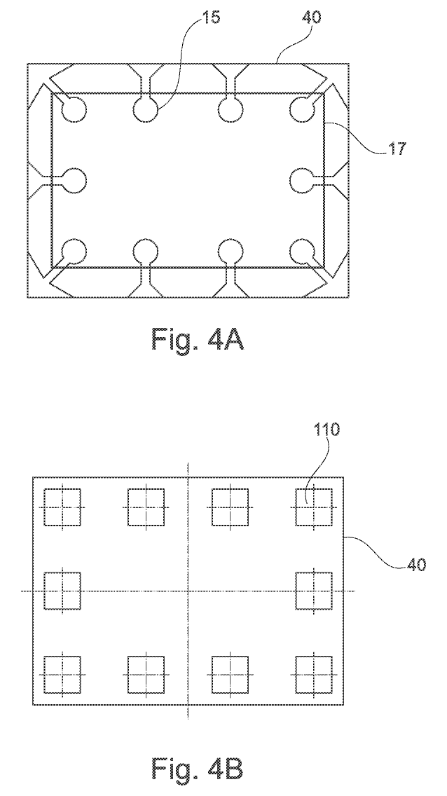

FIGS. 4A and 4B show a device according to a further embodiment, where a single area is shown. A line 40 marks the border of the area along which the device is singulated. Here, ten (10) pads 15 are provided, to which a chip 17 is bonded. FIG. 4A shows a top view, and FIG. 4B shows a bottom view. On the bottom side of FIG. 4B, correspondingly ten conductive portions 110 are provided, to which pads 15 are connected via electrically conducting path going through through holes arranged at the border of the area, to be shared with adjacent areas as discussed previously.

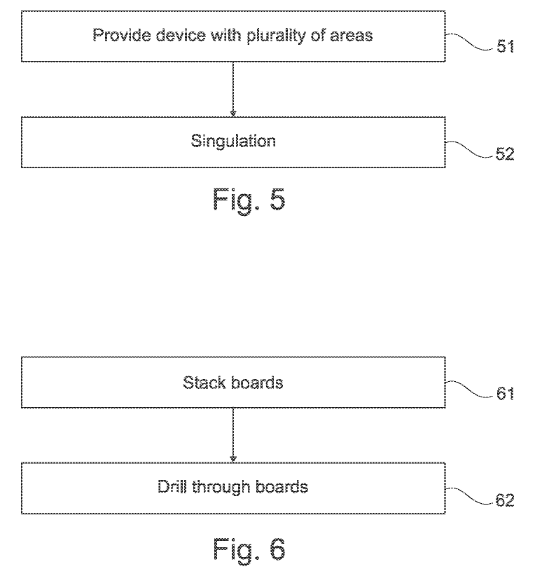

FIG. 5 shows a method according to an embodiment. At 51, a device with a plurality of areas, as shown in FIG. 1A, with chips bonded to the pads, is provided. At 52, a singulation is performed, for example by sawing along saw lines 12, to provide single devices with respective chips.

Through holes may be drilled efficiently by stacking. A corresponding manufacturing method is illustrated in FIG. 6. At 61, a plurality of boards like board 10 of FIG. 1A are stacked. At 62, through holes are formed in all stacked board in a single drilling operation, by drilling at the respective through hole positions through all the stacked boards.

The methods of FIG. 5 and 6 may form part of a complete manufacturing process for devices.

Some embodiments are defined by the following examples.

Example 1. A device, comprising: a board member comprising a first area and a second area on a first side of the board member, the first area including a first electrically conducting pad for bonding to a first chip, the second area including a second electrically conducting pad for bonding to a second chip, the board member further comprising: a through hole between the first side and a second side opposite the first side and arranged at a border between the first area and the second area, a first electrically conducting path from the first electrically conducting pad through the through hole to a first conducting potion on the second side opposite the first area, and a second electrically conducting path from the first electrically conducting pad through the through hole to a second conducting potion on the second side opposite the second area.

Example 2. The device of example 1, wherein a width of the first electrically conducting path on the first side is smaller than a diameter of the first electrically conducting pad, an/or wherein a width of the second electrically conducting path on the first side is smaller than a diameter of the second electrically conducting pad.

Example 3. The device of example 1 or 2, wherein an inner wall of the through hole is provided with an electrically conducting material forming part of both the first electrically conducting path and the second electrically conducting path such that when the first area is separated from the second area, a first part of the electrically conducting material forms a part of the first electrically conducting path and a second part of the electrically conducting layer forms a part of the second electrically conducting path.

Example 4. The device of any one of examples 1 to 3, comprising a plurality of areas including the first area and the second area, wherein each of the areas has a rectangular shape, wherein the areas are arranged in an array.

Example 5. The device of example 4, wherein each of the areas includes one or more electrically conducting pads for bonding to a respective chip to the respective area including the first and second electrically conducting pads, wherein the board member comprises a plurality of through holes including the trough hole provided at borders between adjacent areas, wherein at least some of the through holes provide parts of electrically conducting paths for the adjacent areas including the first and second electrically conducting paths.

Example 6. The device of example 5, wherein the plurality of through holes include a first subset of through holes provided at common edges of adjacent areas and a second subset of through holes provided at common corners of areas.

Example 7. The device of example 6, wherein the through holes of the first subset have a smaller diameter that the through holes of the second subset.

Example 8. The device of any one of examples 1 to 7, further comprising the first chip bonded to the first electrically conducting pad and the second chip bonded to the second electrically conducting pad.

Example 9. The device of example 8, further comprising a cover material closing the through hole on the first side.

Example 10. The device of example 8 or 9, further comprising a molding material encapsulating the first and second chips on the first side.

Example 11. A device, comprising: a board member including: an electrically conducting pad on a first side, an indentation on a side face of the board member, and an electrically conducting path from the electrically conducting pad through the indentation to an electrically conducting portion on the second side; and a chip bonded to the electrically conducting pad.

Example 12. The device of example 11, wherein a width of the electrically conducting path on the first side is smaller than a diameter of the electrically conducting pad.

Example 13. The device of example 11 or 12, wherein the indentation is located at a corner of the board member.

Example 14. The device of any one of examples 11 to 13, comprising a plurality of electrically conducting pads including the electrically conducting pad, wherein the chip is bonded to the plurality of electrically conducting pads, a plurality of indentations on the side face of the board member including the indentation, and a plurality of electrically conducting paths including the electrically conducting path, each of the plurality of electrically conducting paths running from a respective electrically conducting pad through a respective indentation to a respective electrically conducting portion on the second side.

Example 15. A method of manufacturing the device of any one of examples 11 to 14, comprising singulating the areas of the device of any one of examples 8 to 10.

Example 16. A method of manufacturing a plurality of the board members of any one of examples 1 to 10, comprising: stacking a plurality of boards, and drilling the through hole for the plurality of boards in one drilling operation through all the stacked boards.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A device, comprising:
a board member comprising a first area and a second area on a first side of the board member, the first area including a first electrically conducting pad for bonding to a first chip, the second area including a second electrically conducting pad for bonding to a second chip, the board member further comprising:
a through hole between the first side and a second side opposite the first side and arranged at a border between the first area and the second area;
a first electrically conducting path from the first electrically conducting pad through the through hole to a first conducting potion on the second side opposite the first area; and
a second electrically conducting path from the first electrically conducting pad through the through hole to a second conducting potion on the second side opposite the second area.

2. The device of claim 1, wherein a width of the first electrically conducting path on the first side is smaller than a diameter of the first electrically conducting pad.

3. The device of claim 1, wherein a width of the second electrically conducting path on the first side is smaller than a diameter of the second electrically conducting pad.

4. The device of claim 1, wherein an inner wall of the through hole is provided with an electrically conducting material forming part of both the first electrically conducting path and the second electrically conducting path such that when the first area is separated from the second area, a first part of the electrically conducting material forms a part of the first electrically conducting path and a second part of the electrically conducting layer forms a part of the second electrically conducting path.

5. The device of claim 1, further comprising a plurality of areas including the first area and the second area, wherein each of the areas has a rectangular shape, and wherein the areas are arranged in an array.

6. The device of claim 5, wherein each of the areas includes one or more electrically conducting pads for bonding to a respective chip to the respective area including the first and second electrically conducting pads, wherein the board member comprises a plurality of through holes including the trough hole provided at borders between adjacent areas, and wherein at least some of the through holes provide parts of electrically conducting paths for the adjacent areas including the first and second electrically conducting paths.

7. The device of claim 6, wherein the plurality of through holes includes a first subset of through holes provided at common edges of adjacent areas and a second subset of through holes provided at common corners of areas.

8. The device of claim 7, wherein the through holes of the first subset have a smaller diameter that the through holes of the second subset.

9. The device of claim 1, further comprising the first chip bonded to the first electrically conducting pad and the second chip bonded to the second electrically conducting pad.

10. The device of claim 9, further comprising a cover material closing the through hole on the first side.

11. The device of claim 9, further comprising a molding material encapsulating the first and second chips on the first side.

12. A device, comprising:
a board member including: an electrically conducting pad on a first side; an indentation on a side face of the board member; and an electrically conducting path from the electrically conducting pad through the indentation to an electrically conducting portion on the second side; and
a chip bonded to the electrically conducting pad.

13. The device of claim 12, wherein a width of the electrically conducting path on the first side is smaller than a diameter of the electrically conducting pad.

14. The device of claim 12, wherein the indentation is located at a corner of the board member.

15. The device of claim 12, further comprising:
a plurality of electrically conducting pads including the electrically conducting pad, wherein the chip is bonded to the plurality of electrically conducting pads;
a plurality of indentations on the side face of the board member including the indentation; and
a plurality of electrically conducting paths including the electrically conducting path, each of the plurality of electrically conducting paths running from a respective electrically conducting pad through a respective indentation to a respective electrically conducting portion on the second side.

16. A method, comprising:
stacking a plurality of boards, each board comprising a first area and a second area on a first side of the board, the first area including a first electrically conducting pad for bonding to a first chip, the second area including a second electrically conducting pad for bonding to a second chip, each board further comprising: a through hole between the first side and a second side opposite the first side and arranged at a border between the first area and the second area; a first electrically conducting path from the first electrically conducting pad through the through hole to a first conducting potion on the second side opposite the first area; and a second electrically conducting path from the first electrically conducting pad through the through hole to a second conducting potion on the second side opposite the second area; and
drilling the through hole for the plurality of boards in one drilling operation through all the stacked boards.
